(19) United States
(12) Patent Application Publication
(10) Pub. No.: US 2019/0044094 A1
(43) Pub. Date: Feb. 7, 2019

(54) GAS BARRIER FILM, ORGANIC ELECTRONIC DEVICE, SUBSTRATE FOR ORGANIC ELECTROLUMINESCENCE DEVICE, AND ORGANIC ELECTROLUMINESCENCE DEVICE

(71) Applicant: FUJIFILM Corporation, Tokyo (JP)

(72) Inventor: Aya NAKAYAMA, Minamiashigara-shi (JP)

(73) Assignee: FUJIFILM Corporation, Tokyo (JP)

(21) Appl. No.: 16/156,900

(22) Filed: Oct. 10, 2018

Related U.S. Application Data
(63) Continuation of application No. PCT/JP2017/013876, filed on Apr. 3, 2017.

(30) Foreign Application Priority Data
Apr. 11, 2016 (JP) 2016-079147

(51) Int. Cl. H01L 51/52; H01L 51/56; H01L 51/00

(52) U.S. Cl. CPC H01L 51/5253; H01L 51/56; H01L 51/0094; H01L 51/004; H01L 2251/301; H01L 2251/303; H01L 2251/556; H01L 2251/558

(57) ABSTRACT

A gas barrier film includes, in order: a film substrate; a first inorganic layer; and a first organic layer, in which the first inorganic layer is in direct contact with the first organic layer, the first organic layer is a layer formed by curing a composition including (meth)acrylate and a silane coupling agent, the (meth)acrylate has a CLogP of 4.0 or more, and the silane coupling agent has a (meth)acryloyl group and has a volatilization amount of less than 5.0% at 105° C. A substrate for an organic electroluminescence device, an organic electroluminescence device, and an organic electronic device each include the gas barrier film.

### CROSS-REFERENCE TO RELATED APPLICATIONS

This application is a Continuation of PCT International Application No. PCT/JP2017/013876 filed on Apr. 3, 2017, which claims priority under 35 U.S.C § 119(a) to Japanese Patent Application No. 2016-079147 filed on Apr. 11, 2016. Each of the above application(s) is hereby expressly incorporated by reference, in its entirety, into the present application.

### BACKGROUND OF THE INVENTION

### 1. Field of the Invention

The present invention relates to a gas barrier film. The present invention also relates to an organic electronic device, a substrate for an organic electroluminescence device, and an organic electroluminescence device using a gas barrier film.

### 2. Description of the Related Art

In liquid crystal display devices, organic electronic devices, and the like, in place of a glass substrate which has been conventionally used, in recent years, a plastic film substrate has been used. A plastic film substrate is advantageous in point of flexibility and lightweight. Since a plastic film substrate can be produced by a roll-to-roll system, it is advantageous in that the plastic film substrate can be produced at a low cost. A gas barrier film formed using a plastic film substrate has the above advantages, also has a laminated structure of an organic layer and an inorganic layer, which blocks water vapor, oxygen, and the like, and is capable of realizing a low water vapor transmission rate. Such a gas barrier film is also applied as a substrate and a sealing member of an organic electronic device (for example, JP5174517B).

An organic electronic device is required to have higher barrier properties to prevent an organic electronic element from deteriorating due to moisture penetration, so that the performance of the organic electronic device is not affected. JP2015-524494A discloses that an organic electronic element is sealed with a gas barrier film including a layer, which is formed of a curable resin composition including metal oxide particles and a (meth)acrylate having a CLogP of more than 2, as a water trapping layer.

### SUMMARY OF THE INVENTION

In the water trapping layer disclosed in JP2015-524494A, metal oxide particles are used to absorb moisture. However, in the verification by the present inventors, at the time when it was considered to exceed the saturated water absorption of the metal oxide particles, the progress of hydrolysis of the metal oxide particles, the deterioration of the resin, and the deterioration of the inorganic layer occurred, moisture penetrated into the sealed organic electronic element, and thus the organic electronic device using the water trapping layer could not withstand a long-term durability test. In addition, in a device such as an organic electronic device, the amount of moisture retained by the gas barrier film itself is also considered to affect performance, and further improvements are desired for a gas barrier film suitable for being used as sealing or a substrate of an organic electronic device.

In view of the above, an object of the present invention is to provide a gas barrier film having high barrier properties and exhibiting less moisture release from the inside. Particularly, an object of the present invention to provide a gas barrier film which is less likely to lower the performance of an organic electronic device even in a case where the film is used for sealing or a substrate of the organic electronic device. Another object of the present invention is to provide an organic electronic device, particularly, an organic electroluminescence device, an organic electronic element of which is less likely to be deteriorated.

The present inventors have conducted intensive studies for achieving the above objects, have found that the barrier properties of a gas barrier film and the moisture content of an organic layer vary depending on the kinds of a polymerizable compound and additives in a composition for forming an organic layer to be provided on a surface of an inorganic layer, and thus have completed the present invention.

That is, the present invention provides the following [1] to [20].

[1] A gas barrier film comprising, in order: a film substrate; a first inorganic layer; and a first organic layer,

in which the first inorganic layer is in direct contact with the first organic layer,

the first organic layer is a layer formed by curing a composition including (meth)acrylate and a silane coupling agent,

the (meth)acrylate has a CLogP of 4.0 or more, and

the silane coupling agent has a (meth)acryloyl group and has a volatilization amount of less than 5.0% at 105° C.

[2] The gas barrier film according to [1], in which a molecular weight of the silane coupling agent is 300 or more.

[3] The gas barrier film according to [1] or [2], in which the silane coupling agent has four or more (meth)acryloyl groups.

[4] The gas barrier film according to [1] or [2], in which the silane coupling agent includes a linear alkyl group having 6 or more carbon atoms.

[5] The gas barrier film according to any one of [1] to [4], in which the (meth)acrylate has two or more (meth)acryloyl groups.

[6] The gas barrier film according to any one of [1] to [5], in which the first organic layer has a film thickness of 0.1 to 10 μm.

[7] The gas barrier film according to any one of [1] to [6], in which the first inorganic layer is formed of silicon oxynitride or silicon nitride.

[8] The gas barrier film according to any one of [1] to [7], further comprising: a second inorganic layer, in which the first organic layer is in direct contact with the second inorganic layer.

[9] The gas barrier film according to [8], in which the second inorganic layer is formed of silicon oxynitride or silicon nitride.

[10] The gas barrier film according to any one of [1] to [9], in which a glass transition temperature of the (meth)acrylate after curing is 140° C. or higher.

[11] The gas barrier film according to any one of [1] to [10], in which a glass transition temperature of the (meth)acrylate after curing is 180° C. or higher.

[12] The gas barrier film according to any one of [8] to [11], further comprising: a second organic layer, in which the second inorganic layer is in direct contact with the second organic layer.

[13] The gas barrier film according to [12], in which the second organic layer is a layer formed by curing a composition including a (meth)acrylate having a CLogP of 4.0 or more, and a silane coupling agent having a (meth)acryloyl group and having a volatilization amount of less than 5.0% at 105° C.

[14] The gas barrier film according to [12] or [13], in which the second organic layer has a film thickness of 0.1 to 10 μm.

[15] The gas barrier film according to any one of [1] to [14], further comprising: an undercoat organic layer between the film substrate and the first inorganic layer.

[16] An organic electronic device comprising: the gas barrier film according to any one of [1] to [15].

[17] A substrate for an organic electroluminescence device, comprising: the gas barrier film according to any one of [1] to [15]; and an organic electroluminescent element,

in which the organic electroluminescent element is provided on a surface of the gas barrier film, and

the film substrate, the first organic layer, and the organic electroluminescent element are arranged in this order.

[18] The substrate for an organic electroluminescence device according to [17], in which the organic electroluminescent element includes an anode, a light emitting layer, and a cathode in this order, and

the anode is formed by coating.

[19] An organic electroluminescence device comprising: the substrate for an organic electroluminescence device according to [17] or [18].

[20] An organic electroluminescence device comprising: the gas barrier film according to any one of [1] to [15]; an organic electroluminescent element; and a substrate,

in which the organic electroluminescent element is provided on a surface of the substrate, and

the film substrate, the first organic layer, the organic electroluminescent element, and the substrate are arranged in this order.

According to the present invention, a gas barrier film having high barrier properties and exhibiting less moisture release from the inside is provided. It is possible to provide an organic electronic device, particularly, an organic electroluminescence device, an organic electronic element of which is less likely to be deteriorated using the gas barrier film of the present invention.

### DESCRIPTION OF THE PREFERRED EMBODIMENTS

Hereinafter, the contents of the present invention will be described in detail. In the present specification, “to” is used to mean that numerical values described before and after “to” are included in a numerical range as a lower limit value and an upper limit value. In the present specification, “(meth)acrylate” represents “either or both of acrylate and methacrylate”. The same shall be applied to “(meth)acrylic polymer”, “(meth)acryloyl group”, and the like.

### <Gas Barrier Film>

A gas barrier film according to an embodiment of the present invention includes a film substrate (film base material), a first inorganic layer, and a first organic layer in this order. The gas barrier film of the embodiment of the present invention may include other layers. For example, it is preferable that the gas barrier film includes an undercoat organic layer between the film substrate and the first inorganic layer. It is also preferable that the gas barrier film of the embodiment of the present invention includes a film substrate, a first inorganic layer, a first organic layer, and a second inorganic layer in this order. In addition, it is preferable that the gas barrier film of the embodiment of the present invention is formed by alternately laminating two or more organic layers and two or more inorganic layers. Further, the gas barrier film of the embodiment of the present invention may include a protective layer on one of surfaces, particularly, on a surface opposite to the film substrate, as viewed from the first organic layer.

Preferable examples of the layer configuration of the gas barrier film include the followings. The layers are laminated in the described orders of film substrate/inorganic layer/protective layer;

film substrate/first inorganic layer/first organic layer; film substrate/first inorganic layer/first organic layer/second inorganic layer; film substrate/first inorganic layer/first organic layer/second inorganic layer/second organic layer; film substrate/first inorganic layer/first organic layer/second inorganic layer/second organic layer/third inorganic layer; film substrate/first inorganic layer/first organic layer/second inorganic layer/second organic layer/third inorganic layer/third organic layer; film substrate/undercoat organic layer/first inorganic layer/first organic layer; film substrate/undercoat organic layer/first inorganic layer/first organic layer/second inorganic layer; film substrate/undercoat organic layer/first inorganic layer/first organic layer/second inorganic layer/second organic layer; film substrate/undercoat organic layer/first inorganic layer/first organic layer/second inorganic layer/second organic layer/third inorganic layer;

film substrate/undercoat organic layer/first inorganic layer/first organic layer/second inorganic layer/second organic layer/third inorganic layer/third organic layer; film substrate/first inorganic layer/first organic layer/second inorganic layer/protective layer; film substrate/first inorganic layer/first organic layer/second inorganic layer/second organic layer/third inorganic layer/protective layer; film substrate/undercoat organic layer/first inorganic layer/first organic layer/second inorganic layer/protective layer; and film substrate/undercoat organic layer/first inorganic layer/first organic layer/second inorganic layer/second organic layer/third inorganic layer/protective layer.

The number of layers constituting the gas barrier film is not particularly limited, but the number of layers is typically preferably 3 to 15 and more preferably 3 to 8. The gas barrier film of the embodiment of the present invention may have a functional layer other than the film substrate, the first organic layer, the first inorganic layer, and the protective layer. The functional layer is described in detail in paragraphs 0036 to 0038 of JP2006-289627A. Examples of functional layers other than these functional layers include a matting agent layer, a solvent resistant layer, an antistatic layer, a flattening layer, an adhesiveness improving layer, a light shielding layer, an antireflection layer, a hard coat layer, a stress relaxing layer, an antifogging layer, an antifouling layer, and a layer to be printed.

The film thickness of the gas barrier film is preferably 10 μm to 200 μm and more preferably 20 μm to 150 μm.

### [Film Substrate]

The film substrate may be a plastic film. The plastic film to be used is not particularly limited in terms of a material, thickness, or the like as long as the film can hold a laminate including an inorganic layer and an organic layer to be provided thereon and can be selected appropriately depending on the purpose of use or the like. Specifically, the plastic film includes thermoplastic resins such as polyester resin such as polyethylene terephthalate (PET) or polyethylene naphthalate (PEN), methacrylic resin, methacrylic acid-maleic acid copolymer, polystyrene resin, transparent fluorine-containing resin, polyimide, fluorinated polyimide resin, polyamide resin, polyamide-imide resin, polyetherimide resin, cellulose acylate resin, polyurethane resin, polyether ether ketone resin, polycarbonate resin, alicyclic polyolefin resin, polyarylate resin, polyether sulfone resin, polysulfone resin, cycloolefin copolymer, fluorene ring-modified polycarbonate resin, alicyclic-modified polycarbonate resin, fluorene ring-modified polyester resin, and acryloyl compound. As the film substrate, polyester resin can be particularly preferably used. The film thickness of the film substrate is preferably 8 μm to 200 μm and more preferably 18 μm to 150 μm.

The film substrate may have a topcoat layer. The topcoat layer is not particularly limited but may be formed of polyester, polyurethane, polyolefin, acrylic resins, styrene butadiene copolymers. The film thickness of the topcoat layer is preferably 0.01 μm to 5.0 μm and more preferably 0.02 μm to 1 μm.

In a case where the film substrate has a topcoat layer, the film substrate preferably has the topcoat layer on the surface on a first organic layer side.

### [First Organic Layer]

The gas barrier film of the embodiment of the present invention includes the first organic layer. The gas barrier film of the embodiment of the present invention may or may not include organic layers other than the first organic layer. In the present specification, the organic layer means a layer formed by curing a composition including a polymerizable compound and includes the first organic layer, the second organic layer, the undercoat organic layer, and the like.

The compositions, film thicknesses, and the like of the first organic layer and other organic layers may be the same as or different from each other.

In the present specification, the first organic layer is a random layer in which the interface of an organic layer on a film substrate side is in direct contact with the inorganic layer among the organic layers provided on the film substrate. Further, an inorganic layer that is in direct contact with the first organic layer on a surface of the first organic layer on the film substrate side is the first inorganic layer. The first inorganic layer is preferably an inorganic layer that is in direct contact with an undercoat organic layer, which will be described later, and particularly preferably an inorganic layer that is in direct contact with an undercoat organic layer provided on the surface of the film substrate.

In addition, it is preferable that the first organic layer is in direct contact with the second inorganic layer on a surface opposite to the surface that is in direct contact with the first inorganic layer. That is, it is preferable that the first organic layer is interposed between two inorganic layers and is in direct contact with the two inorganic layers. In the configuration in which the first organic layer is interposed between two inorganic layers, the moisture content of the first organic layer is less likely to be lowered depending on a drying step or the like after a gas barrier film is produced. However, since the first organic layer is formed of a material that hardly contains moisture, this configuration is preferable.

A second organic layer may be further provided on the second inorganic layer. In the same manner, a third inorganic layer and a third organic layer may be provided, and further, a fourth organic layer, and a fifth organic layer may be present by laminating an inorganic layer and an organic layer.

The film thickness of the first organic layer is preferably 0.1 to 10 μm and more preferably 0.5 to 5.0 μm.

The moisture content of the first organic layer is preferably less than 1.0%. Within this range, a gas barrier film exhibiting less moisture release from the inside can be provided. The moisture content is preferably 0.7% or less, more preferably 0.6% or less, and even more preferably 0.5% or less.

In the present specification, the moisture content is a value obtained by a Karl Fischer method according to the description of JIS K0113. In addition, the moisture content is a value measured after an object to be measured is dried overnight in a vacuum oven at 0.133 Pa (1×10⁻³ torr) and 110° C. and then is left to stand under the environment of 25° C. and 50% relative humidity (RH) for 3 days.

(Composition for Forming First Organic Layer)

A composition for forming a first organic layer to form the first organic layer includes (meth)acrylate and a silane coupling agent. The composition for forming a first organic layer may include other additives such as a polymerization initiator.

((Meth)Acrylate)

The composition for forming a first organic layer includes a (meth)acrylate having a CLogP of 4.0 or more as a polymerizable compound. The CLogP is more preferably 4.2 or more and even more preferably 5.0 or more.

The ClogP value is a value obtained by calculating a common logarithm logP of a partition coefficient P to 1-octanol and water and is a value that is an index of hydrophobicity. A higher ClogP value indicates higher hydrophobicity. In the calculation of the ClogP value, a ClogP value estimation program (a CLOGP program incorporated in PC Models from Daylight Chemical Information Systems) can be used and also a value obtained using ChemDraw or http://www.vcclab.org/lab/alogps/start.html may be used.

By using such a high hydrophobic (meth)acrylate, the first organic layer can be made to have a composition that hardly contains moisture.

The (meth)acrylate having a CLogP of 4.0 or more preferably has two or more (meth)acryloyl groups.

As the (meth)acrylate having a CLogP of 4.0 or more, for example, among (meth)acrylates represented by any of Formulae (1) to (8) below, (meth)acrylates having a calculated CLogP value of 4.0 or more can be used.

In Formulae (1) to (8) and (10), an alkyl group may be either linear or branched. Examples of alkyl groups include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, and an isohexyl group. In addition, in Formulae (1) to (8) and (10), examples of alkylene groups include divalent groups obtained by removing any one hydrogen atom from each of the example of the alkyl group. The same applies to an alkyleneoxy group.

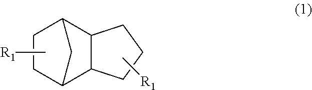

(In the formula, R₁'s each independently represent a substituent represented by Formula (10) below.)

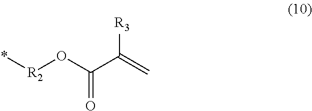

(In the formula, R₂ represents a single bond, an alkylene group having 1 to 6 carbon atoms, an alkyleneoxy group, or a repeating structure of an alkyleneoxy group. R₃ represents a hydrogen atom or a methyl group. * indicates a position to be bonded to an alicyclic skeleton of Formula (1).)

Specific examples of the (meth)acrylate represented by Formula (1) may include tricyclodecanedimethanol diacrylate and tricyclodecane dimethanol dimethacrylate. As commercially available products of the (meth)acrylate represented by Formula (1), A-DCP (manufactured by manufactured by Shin-Nakamura Chemical Co., Ltd.), DCP (manufactured by manufactured by Shin-Nakamura Chemical Co., Ltd.), IRR214-K (manufactured by Daicel-Allnex Ltd.), LIGHT ACRYLATE DCP-A (manufactured by Kyoeisha Chemical Co., Ltd.), and the like are available.

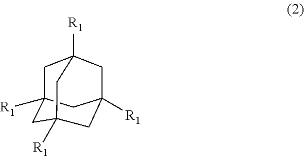

(In the formula, R₁ has the same meaning as R₁ in Formula (1).)

Specific examples of the (meth)acrylate represented by Formula (2) include 1,3,5-adamantane triol trimethacrylate, 1,3-adamantane dimethanol diacrylate, 1,3-adamantane dimethanol dimethacrylate, 1,3,5-adamantane trimethanol triacrylate and 1,3,5-adamantane trimethanol trimethacrylate. As commercially available products of the (meth)acrylate represented by Formula (2), DIAPURESTE ADTM (manufactured by Mitsubishi Gas Chemical Co., Ltd.), and the like are available.

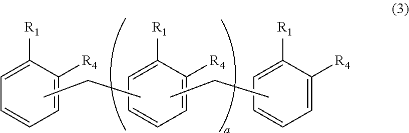

(In the formula, R₁ has the same meaning as R₁ in Formula (1). R₄'s each represent a hydrogen atom or a methyl group. a is an integer of 1 to 20.)

Specific examples of the (meth)acrylate represented by Formula (3) include compounds represented by the following structural formula.

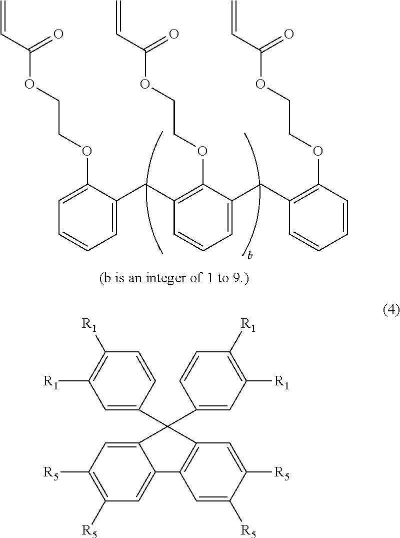

(In the formula, R₁ has the same meaning as R₁ in Formula (1). R₅'s each represent a hydrogen atom, an alkyl group having 1 to 6 carbon atoms, a cyclohexyl group, or a phenyl group, or adjacent R₅'s may be bonded to form a hydrocarbon ring having 3 to 8 carbon atoms.) Examples of the hydrocarbon ring include a benzene ring.

Specific examples of the (meth)acrylate represented by Formula (4) include compounds represented by the following structural formulae.

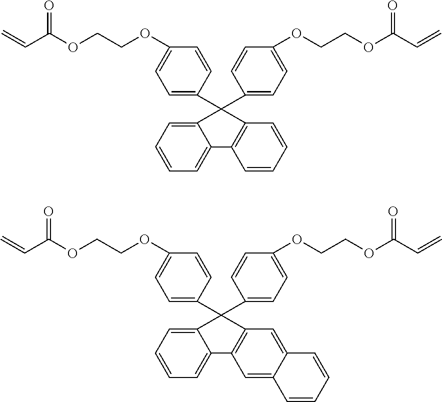

As commercially available products of the (meth)acrylate represented by Formula (4), A-BPEF (manufactured by Shin-Nakamura Chemical Co., Ltd.), OGSOL EA200 (manufactured by Osaka Gas Chemicals Co., Ltd.), and the like are available.

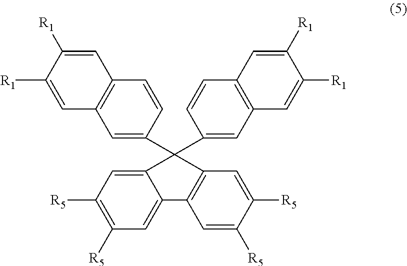

(In the formula, R₁ and R₅ each have the same meaning as R₁ in Formula (1) and R₅ in Formula (4).)

Specific examples of the (meth)acrylate represented by Formula (5) include compounds represented by the following structural formulae.

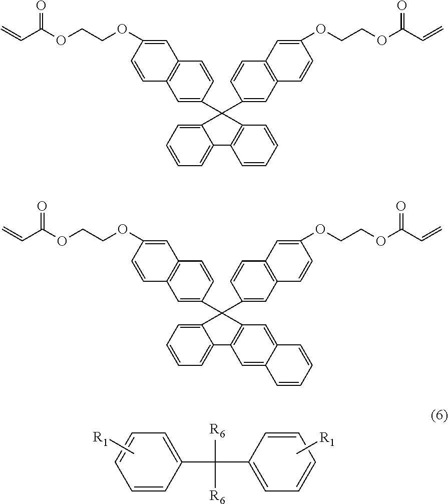

(In the formula, R₁ has the same meaning as R₁ in Formula (1). R₆'s each represent a hydrogen atom or an alkyl group having 1 to 6 carbon atoms.)

Specific examples of the (meth)acrylate represented by Formula (6) include compounds represented by the following structural formulae.

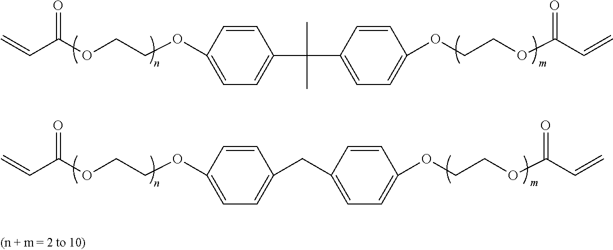

As commercially available products of the (meth)acrylate represented by Formula (6), ABE-300, A-BPE-4, and A-BPE-10 (manufactured by Shin-Nakamura Chemical Co., Ltd.), EBECRYL150 (manufactured by Daicel-Allnex Ltd.), LIGHT ACRYLATE BP-4EL (manufactured by Kyoeisha Chemical Co., Ltd.), ARONIX M211B and ARONIX M208 (manufactured by Toagosei Co., Ltd.), and the like are available.

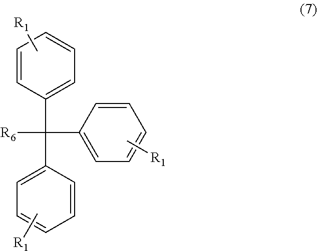

(In the formula, R₁ and R₆ each have the same meaning as R₁ in Formula (1) and R₆ in Formula (6).)

Specific examples of the (meth)acrylate represented by Formula (7) include compounds represented by the following structural formulae.

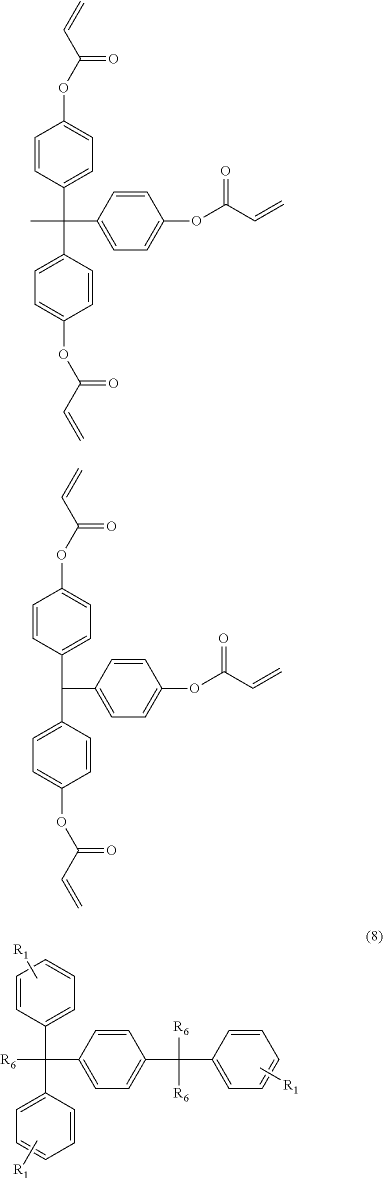

(In the formula, R₁ and R₆ each have the same meaning as R₁ in Formula (1) and R₆ in Formula (6).)

Specific examples of the (meth)acrylate represented by Formula (8) include compounds represented by the following structural formula.

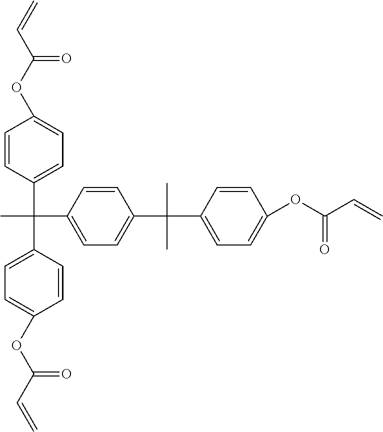 [SMILES: C=CC(=O)Oc1ccc(C(C)(C)c2ccc(C(C)(c3ccc(OC(=O)C=C)cc3)c3ccc(OC(=O)C=C)cc3)cc2)cc1]

In a case of a gas barrier film including a second inorganic layer, the glass transition temperature of the (meth)acrylate after curing is preferably 140° C. or higher and more preferably 180° C. or higher. By using the (meth)acrylate having a glass transition temperature of 140° C. or higher after curing, even in a case where a second inorganic layer is formed on the surface of a first organic layer to be formed by CVD or the like, there are advantages in that the surface of the first organic layer can be kept flat and a dense inorganic layer can be formed.

Here, the glass transition temperature of the (meth)acrylate after curing is a glass transition temperature of a homopolymer obtained by polymerizing (meth)acrylate.

In the present specification, the glass transition temperature (hereinafter, abbreviated as Tg in some cases) is calculated by a differential scanning calorimetry (DSC). The measurement conditions given below can be used as an example of specific measurement conditions of DSC.

DSC device: DSC 6200 manufactured by SII Technology, Inc.

Atmosphere in measurement room: nitrogen (50 mL/min)

Temperature increasing speed: 10° C./min

Measurement starting temperature: 0° C.

Measurement ending temperature: 200° C.

Sample pan: pan made of aluminum

Mass of measured sample: 5 mg

Calculation of Tg: an intermediate temperature between the decrease starting point and the decrease ending point in the DSC chart is set as Tg. Here, measurement is performed on the same sample two times and the second measurement result is adopted.

A composition in which 0.1% to 5.0% by mole of a polymerization initiator is added to (meth)acrylate is irradiated with ultraviolet rays or the like, and the obtained cured article is subjected to DSC so that the glass transition temperature of (meth)acrylate after curing can be obtained.

In the composition for forming a first organic layer, two or more (meth)acrylates having a CLogP of 4.0 or more may be included.

The content of the (meth)acrylate having a CLogP of 4.0 or more in the composition for forming a first organic layer is preferably 60% by mass or more, more preferably 70% by mass or more, even more preferably 80% by mass or more, and particularly preferably 90% by mass or more with respect to the total mass of a solid content of the composition for forming a first organic layer. In the present specification, the “solid content” means the remainder after a volatile content (such as a solvent) is volatilized and the “total mass of the solid content” means the mass of the remainder after the volatile content is volatilized.

(Another Polymerizable Compound)

The composition for forming a first organic layer may include another polymerizable compound of the (meth)acrylate having a CLogP of 4.0 or more.

Examples of another polymerizable compound include a compound having another ethylenically unsaturated bond at a terminal or a side chain, and a compound having epoxy or oxetane at a terminal or a side chain. As another polymerizable compound, a compound having an ethylenically unsaturated bond at a terminal or a side chain is particularly preferable. Examples of the compound having an ethylenically unsaturated bond at a terminal or a side chain include a (meth)acrylate-based compound, an acrylamide-based compound, and maleic anhydride. A (meth)acrylate-based compound is preferable, and an acrylate-based compound is particularly preferable.

As the (meth)acrylate-based compound, (meth)acrylate, urethane (meth)acrylate, polyester (meth)acrylate, epoxy (meth)acrylate, or the like is preferable.

As the (meth)acrylate-based compound, specifically, compounds described in paragraphs 0024 to 0036 of JP2013-043382A, compounds described in paragraphs 0036 to 0048 of JP2013-043384A, and compounds described in WO2013/047524 can be used. Any of the above (meth)acrylates having a carbon ring described in the description of the composition for forming a protective layer described later may be used.

The content of another polymerizable compound in the composition for forming a first organic layer is preferably 40% by mass or less, more preferably 30% by mass or less, even more preferably 20% by mass or less, and particularly preferably 10% by mass or less with respect to the total mass of the solid content of the composition for forming a first organic layer.

(Silane Coupling Agent)

In the gas barrier film having a laminated structure of an organic layer and an inorganic layer, barrier properties may be deteriorated due to insufficient adhesion between the layers. From this viewpoint, generally, it is preferable to use a silane coupling agent in the composition for forming an organic layer in order to improve interlaminar adhesion. However, the organic layer tends to more easily contain water depending on the silane coupling agent. The first organic layer of the gas barrier film of the embodiment of the present invention is formed of a composition for forming a first organic layer including a silane coupling agent having a (meth)acryloyl group and having a volatilization amount of less than 5.0% at 105° C. The present inventors have found that by forming the first organic layer using the composition including the silane coupling agent having the above-mentioned highly hydrophobic (meth)acrylate and having a volatilization amount of less than 5.0% at 105° C., the adhesiveness between the first organic layer and the first inorganic layer can be improved and the moisture content of the first organic layer can also be kept low.

In addition, by using a silane coupling agent having a volatilization amount of less than 5.0% at 105° C. as the silane coupling agent, it is possible to prevent the production step of the gas barrier film from being affected by volatilization of the silane coupling agent itself or to prevent an organic electronic device or the like from being affected by volatilization of the silane coupling agent remaining in the organic layer at the time of use of the gas barrier film.

The volatilization amount of the silane coupling agent at 105° C. is measured and calculated in the procedure shown in the example. The volatilization amount of the silane coupling agent at 105° C. is preferably less than 4.0% and more preferably 3.0% or less.

The molecular weight of the silane coupling agent used in the composition for forming a first organic layer is preferably 300 or more.

Preferable examples of the silane coupling agent used in the composition for forming a first organic layer includes a silane coupling agent having four or more (meth)acryloyl groups and a silane coupling agent including a linear alkyl group having 6 or more carbon atoms.

The silane coupling agent having four or more (meth)acryloyl groups is more preferably has five or more (meth)acryloyl groups. As a commercially available product of the silane coupling agent having four or more (meth)acryloyl groups, X-12-1050 manufactured by Shin-Etsu Chemical Co., Ltd. or the like can be used.

Examples of the silane coupling agent including a linear alkyl group having 6 or more carbon atoms include compounds represented by Formula I below.

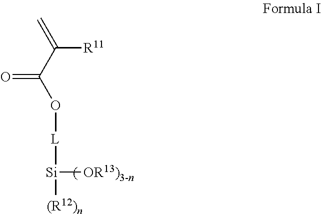

In the formula, R¹¹ independently represents a hydrogen atom or a methyl group, R¹² represents a halogen element or an alkyl group, R¹³ represents a hydrogen atom or an alkyl group, L represents a linear alkyl group having 6 to 16 carbon atoms, and n represents any integer of 0 to 2.

Examples of the halogen element include a chlorine atom, a bromine atom, a fluorine atom, and an iodine atom.

The number of carbon atoms of the alkyl group or the alkyl group in the substituent including the alkyl group among substituents described below is preferably 1 to 12, more preferably 1 to 9, and even more preferably 1 to 6. Specific examples of the alkyl group include a methyl group, an ethyl group, a propyl group, a butyl group, a pentyl group, and a hexyl group. The alkyl group may be linear, branched, or cyclic, but is preferably a linear alkyl group.

Examples of L include a 1,6-hexylene group, a 1,9-nonylene group, a 1,12-dodecylene group, and a 1,16-hexadecylene group.

As commercially available products of the compound represented by Formula I, KBM-5803 (8-methacryloxyoctyltrimethoxysilane: manufactured by Shin-Etsu Chemical Co., Ltd.) and the like are available.

The content of the silane coupling agent in the composition for forming a first organic layer is preferably 0.01% to 10% by mass and more preferably 0.1% to 5.0% by mass with respect to the total mass of the solid content of the composition for forming a first organic layer.

(Polymerization Initiator)

The composition for forming a first organic layer preferably includes a polymerization initiator. In a case of using a polymerization initiator, the content thereof is preferably 0.1% to 5.0% by mole and more preferably 0.5% to 2.0% by mole of the total amount of the polymerizable compound such as the (meth)acrylate. By adopting such a composition, a polymerization reaction via an active component generation reaction can be appropriately controlled. Examples of photopolymerization initiators include Irgacure series (for example, IRGACURE 651, IRGACURE 754, IRGACURE 184, IRGACURE 2959, IRGACURE 907, IRGACURE 369, IRGACURE 379, and IRGACURE 819), Darocure series (for example, DAROCURE TPO and DAROCURE 1173), and Quantacure PDO, all commercially available from BASF SE, and Esacure series (for example, ESACURE TZM, ESACURE TZT, and ESACURE KT046) all commercially available from Lamberti S.p.A.

(Polymer)

The composition for forming a first organic layer may or may not include a polymer. Examples of the polymer include polyester, polyolefin, acrylic urethane resin, styrene acrylic resins, polyvinylidene chloride, and (meth)acrylic polymers used in the protective layer described later.

In a case where the composition for forming a first organic layer includes a polymer, the content of the polymer is preferably less than 15% by mass, more preferably less than 10% by mass, even more preferably less than 5.0% by mass, and particularly preferably 3.0% by mass or less with respect to the total mass of the solid content of the composition for forming an organic layer. By incorporating the (meth)acrylic polymer at a content of less than 5.0% by mass, a smooth inorganic layer can be formed on the organic layer.

(Inorganic Particles)

The composition for forming a first organic layer may include inorganic particles. Examples of inorganic particles include fine particles formed of one or more selected from the group consisting of silicon oxide such as silica, titanium oxide, aluminum oxide, tin oxide, indium oxide, ITO, zinc oxide, zirconium oxide, magnesium oxide, calcium carbonate, talc, clay, calcined kaolin, calcined calcium silicate, hydrated calcium silicate, aluminum silicate, magnesium silicate, and calcium phosphate. Particularly, silicon oxide, titanium oxide, aluminum oxide, zirconium oxide, magnesium oxide, or the like is preferably used.

The content of the inorganic particles in the composition for forming a first organic layer is preferably 0.01% to 25% by mass, more preferably 0.01% to 10% by mass, even more preferably 0.01% to 5.0% by mass, and particularly preferably 0.01% to 1.0% by mass with respect to the total mass of the solid content of the composition for forming a first organic layer. By setting the content within the above range, alcohol and water are not easily allowed to be released under a high temperature and high humidity environment and the inorganic layer is not easily allowed to be deteriorated.

(Solvent)

The composition for forming a first organic layer may include a solvent. Examples of the solvent include ketones such as methyl ethyl ketone (MEK), or ester-based solvents: 2-butanone, propylene glycol monoethyl ether acetate (PGMEA), cyclohexanone, and a mixed solvent of any two or more solvents of these solvents. Among these, methyl ethyl ketone is preferable.

The content of the solvent of the composition for forming a first organic layer is preferably 50% to 97% by mass and more preferably 60% to 95% by mass with respect to the total amount of the composition for forming a first organic layer when the first organic layer is formed (when the composition for forming a first organic layer is applied).

(Method of Preparing First Organic Layer)

The first organic layer is prepared by applying the composition for forming a first organic layer in layers. The composition for forming a first organic layer may be applied to the surface of the first inorganic layer. Examples of the method for application include a dip coating method, an air knife coating method, a curtain coating method, a roller coating method, a wire bar coating method, a gravure coating method, a slide coating method, or an extrusion coating method (also referred to as a die coating method) using a hopper described in U.S. Pat. No. 2,681,294A and among these, an extrusion coating method can be preferably adopted.

The composition for forming a first organic layer may be dried as a coating film after the composition is applied.

The composition for forming a first organic layer may be cured by light (such as ultraviolet rays), electron beams, or heat rays and is preferably cured by light. Particularly, it is preferable that while the composition for forming the first organic layer is being heated at a temperature of 25° C. or higher (for example, 30° C. to 130° C.), the composition is cured. By promoting the free motion of the composition for forming a first organic layer by heating, the composition can be effectively cured, and the film can be formed without damaging the film substrate or the like.

The light for irradiation may be ultraviolet rays using a high pressure mercury lamp or a low pressure mercury lamp as a light source. The irradiation energy is preferably 0.1 J/cm² or more and more preferably 0.5 J/cm² or more.

It is preferable that an oxygen concentration or oxygen partial pressure in the polymerization is set to be low since the polymerizable compound such as (meth)acrylate suffers polymerization inhibition by oxygen in the air. In a case of reducing the oxygen concentration at the time of the polymerization by a nitrogen substitution method, the oxygen concentration is preferably 2% or less and more preferably 0.5% or less. In a case where the oxygen partial pressure at the time of the polymerization is to be reduced by a pressure reducing method, the total pressure is preferably 1000 Pa or less and more preferably 100 Pa or less.

The polymerization rate of the polymerizable compound, such as (meth)acrylate, in the composition for forming a first organic layer after curing is preferably 20% by mass or more, more preferably 30% by mass or more, and particularly preferably 50% by mass or more. The polymerization rate denoted here means a proportion of reacted polymerizable groups among all the polymerizable groups (such as acryloyl group and methacryloyl group) in the monomer mixture. The polymerization rate can be determined quantitatively by an infrared absorption method.

It is preferable that the first organic layer is smooth and has a high film hardness. The smoothness of the first organic layer is preferably less than 3 nm and more preferably less than 1 nm as an average roughness in 1 μm square (Ra value).

Although the film thickness of the first organic layer is not particularly limited, from the viewpoint of brittleness and light transmittance, the film thickness is preferably 50 nm to 5000 nm and more preferably 200 nm to 3500 nm.

It is required that foreign matter such as particles and protrusions are not present on the surface of the first organic layer. Therefore, it is preferable that the first organic layer is formed in a clean room. The degree of cleanliness is preferably class 10000 or lower and more preferably class 1000 or lower.

It is preferable that the hardness of the first organic layer is high. In a case where the hardness of the organic layer is high, an inorganic layer to be formed on the surface thereof is smoothly is formed. As a result, it is found that the barrier capability is improved. The hardness of the organic layer can be denoted as a microhardness based on the nanoindentation method. The microhardness of the first organic layer is preferably 0.1 GPa or higher and more preferably 0.3 GPa or higher.

[Second Organic Layer and the Like]

The gas barrier film of the embodiment of the present invention may include the second organic layer as described above. The gas barrier film may further include third, fourth, fifth, and higher organic layers sequentially from the film substrate side by alternately laminating inorganic layers and organic layers. In the present specification, organic layers to be laminated on the first organic layer are collectively referred to as a second organic layer and the like in some cases.

The film thickness of each of the second organic layer and the like is preferably 0.1 to 10 μm and more preferably 0.5 to 5.0 μm.

The second organic layer and the like can be formed by curing a composition for forming an organic layer including a polymerizable compound.

A composition for forming a second organic layer and the like for forming the second organic layer or the like preferably has a composition corresponding to the composition for forming a first organic layer described above. Particularly, in a case where the second organic layer and the like become surface layers of the gas barrier film of the embodiment of the present invention, the composition for forming a second organic layer and the like preferably has a composition corresponding to the composition for forming a first organic layer described above. Due to this composition, a second organic layer and the like having a low moisture content are formed and thus an organic electronic element to be formed on the surface thereof or the like is not deteriorated.

In the same gas barrier film, the composition for forming a second organic layer and the like preferably has the same composition as the composition for forming a first organic layer.

However, the composition for forming a second organic layer and the like may or may not include the (meth)acrylate having a CLogP of 4.0 or more. For example, as a polymerizable compound, instead of the (meth)acrylate having a CLogP of 4.0 or more, the composition may include another polymerizable compound described in the above composition for forming a first organic layer. The composition for forming a second organic layer and the like may include a (meth)acrylate having a CLogP of 4.0 or more and a silane coupling agent having a (meth)acryloyl group and having a volatilization amount of less than 5.0% at 105° C.

In addition, the composition for forming a second organic layer and the like may include a silane coupling agent. In a case where the composition includes a silane coupling agent, the silane coupling agent is not limited to a silane coupling agent having the (meth)acryloyl group and having a volatilization amount of less than 5.0% at 105° C. The silane coupling agent may be a silane coupling agent represented by Formula (1) described in WO2013/146069, a silane coupling agent represented by Formula (I) described in WO2013/027786, or the like, but a silane coupling agent having a (meth)acryloyl group and a volatilization amount of less than 5.0% at 105° C. is preferably used.

The composition for forming a second organic layer and the like may include a polymerizable compound in the same amount as the polymerizable compound in the composition for forming a first organic layer. The composition for forming a second organic layer and the like may include other components such as a polymerization initiator. As for other components, the description of the above composition for forming a first organic layer can be referred to.

In addition, the second organic layer can be formed in the same manner as in the formation of the first organic layer except that the composition is applied to the surface of the second inorganic layer and the like.

Undercoat Organic Layer

The gas barrier film of the embodiment of the present invention preferably includes an undercoat organic layer. The undercoat organic layer is an organic layer included between the film substrate and the first inorganic layer. The undercoat organic layer is preferably an organic layer provided on the surface of the inorganic layer (is preferably an organic layer different from the first organic layer) and is more preferably an organic layer provided on the surface of the film substrate.

The film thickness of the undercoat organic layer is preferably 0.1 to 10 μm and more preferably 0.5 to 5.0 μm. In a case where the film substrate has a topcoat layer, the film thickness may be thinner by 0.01 μm to 5.0 μm due to this topcoat layer.

The undercoat organic layer can be formed by curing a composition for forming an undercoat organic layer including a polymerizable compound.

The composition for forming an undercoat organic layer may be the same as or different from the composition for forming a first organic layer. The composition for forming an undercoat organic layer, particularly, the composition for forming an undercoat organic layer not provided on the surface of the inorganic layer may substantially include a silane coupling agent, and for example, the content of the silane coupling agent in the composition for forming an undercoat organic layer is preferably less than 3.0% by mass and more preferably less than 1.0% by mass with respect to the total mass of the solid content of the composition for forming an undercoat organic layer. For example, the composition for forming a first organic layer in which the content of the silane coupling agent is less than 3.0% by mass or less than 1.0% by mass may be used to form an undercoat organic layer.

The composition for forming an undercoat organic layer may or may not include the (meth)acrylate having a CLogP of 4.0 or more, and instead of the polymerizable compound, for example, the composition may include another polymerizable compound described in the above composition for forming a first organic layer.

The glass transition temperature of the polymerizable compound in the composition for forming an undercoat organic layer after curing is preferably 140° C. or higher and more preferably 180° C. or higher. By using the polymerizable compound having a glass transition temperature of 140° C. or higher after curing, even in a case where an inorganic layer is formed on the surface of an undercoat organic layer to be formed by CVD or the like, there are advantages in that the surface of the undercoat organic layer can be kept flat and a dense inorganic layer can be formed. Here, the glass transition temperature after curing is a glass transition temperature of a homopolymer obtained by polymerizing a polymerizable compound. For example, the glass transition temperature can be obtained by irradiating a composition in which 0.1% to 5.0% by mole of a polymerization initiator is added to a polymerizable compound with ultraviolet rays and subjecting the obtained cured article to differential scanning calorimetry in the above method.

The composition for forming an undercoat organic layer may include other components such as a polymerization initiator. As for other components, the description in the above composition for forming a first organic layer can be referred to.

In addition, the undercoat organic layer can be formed in the same manner as in the formation of the first organic layer except that the composition for forming an undercoat organic layer is applied onto the film substrate, preferably, to the surface of the film substrate.

[Inorganic Layer]

The inorganic layer is typically a thin film layer formed of a metal compound. In the present specification, in a case where an inorganic layer is simply mentioned, the inorganic layer means including the first inorganic layer, the second inorganic layer, the third inorganic layer, the fourth inorganic layer, the fifth inorganic layer, and the like. Further, in a case where other inorganic layers are included between the first inorganic layer and the film substrate, these inorganic layers are also included. As a method of forming the inorganic layer, any method can be used as long as the desired thin film can be formed. Examples of the method include physical vapor deposition methods (PVD) such as a vapor deposition method, a sputtering method and an ion plating method, various chemical vapor deposition methods (CVD), and liquid phase growth methods such as plating and a sol-gel method. The inorganic layer is preferably formed by a chemical vapor deposition method. The inorganic layer formed by a chemical vapor deposition method has a smooth surface and thus the adhesiveness with the organic layer provided on the surface thereof may be reduced. In the gas barrier film of the embodiment of the present invention, by using the composition for forming a first organic layer, even in a case where an organic layer is provided on the surface of the inorganic layer formed by a chemical vapor deposition method, it is possible to obtain sufficient adhesion between the inorganic layer and the organic layer.

Components included in the inorganic layer are not particularly limited as long as the components satisfy a gas barrier performance, and examples thereof include a metal oxide, a metal nitride, a metal carbide, a metal oxynitride and a metal oxycarbide, and an oxide, a nitride, a carbide, an oxynitride, an oxycarbide or the like containing one or more metals selected from Si, Al, In, Sn, Zn, Ti, Cu, Ce, and Ta can be used preferably. Among these, an oxide, a nitride or an oxynitride of a metal selected from Si, Al, In, Sn, Zn, and Ti is preferable, and particularly, an oxide of Si, a nitride of Si, an oxynitride of Si, an oxide of Al, a nitride of Al, or an oxynitride of Al is preferable. These may contain another element as a subcomponent.

As the inorganic layer, particularly, inorganic layers including silicon (Si) are preferable. This is because the inorganic layers have higher transparency and further excellent gas barrier properties. Among these, an inorganic layer including silicon oxynitride nitride or silicon nitride is particularly preferable.

Particularly, it is preferable that the first inorganic layer is an inorganic layer including Si. In a case where the first organic layer is formed on the surface of the inorganic layer including Si by the composition for forming a first organic layer including the silane coupling agent, the adhesion between the first inorganic layer and the first organic layer is particularly improved.

The component included in the inorganic layer may include hydrogen, but the hydrogen concentration measured by hydrogen forward scattering analysis is preferably 30% or less.

The smoothness of the inorganic layer is preferably less than 3 nm and more preferably 1 nm or less as an average roughness in 1 μm square (a square having one side of 1 μm) (Ra value).

The film thickness of the inorganic layer is not particularly limited. Typically, the thickness of the single inorganic layer is in a range of 5 to 500 nm, preferably 10 to 200 nm, and more preferably 15 to 50 nm. The single inorganic layer may have a laminated structure having a plurality of sub-layers. In this case, the respective compositions of each sub-layer may be the same as or different from each other.

In a case where the gas barrier film of the embodiment of the present invention includes two or more inorganic layers, the compositions, formation methods, film thicknesses, and the like of two or more inorganic layers may be the same as or different from each other. The compositions of two or more inorganic layers are preferably the same as each other and the compositions and formation methods thereof are more preferably the same as each other.

(Lamination of Organic Layer and Inorganic Layer)

Lamination of an organic layer and an inorganic layer can be conducted by successively and repeatedly forming an organic layer and an inorganic layer according to a desired layer configuration.

[Protective Layer]

The gas barrier film of the embodiment of the present invention may have the first organic layer or the second organic layer, or the like or may have the second inorganic layer on one surface thereof. Further, the gas barrier film of the embodiment of the present invention preferably has a protective layer on at least one surface thereof, particularly, on the surface opposite to the film substrate side in the interface of the first organic layer. By providing the protective layer, high scratch resistance is obtained in the gas barrier film and particularly, the inorganic layer related to barrier properties can be protected.

The protective layer is a kind of organic layer which will be described above, but in the present specification, the protective layer refers to an organic layer that is provided on at least one surface of the gas barrier film to be in direct contact with the inorganic layer. It is preferable that the protective layer is in direct contact with at least one inorganic layer in the gas barrier film. Further, the protective layer has the properties and composition described below

The protective layer is preferably a protective layer having a moisture content of less than 1.0%. By providing such a protective layer, a surface with less moisture release can be provided to the gas barrier film. The moisture content is preferably 0.7% or less, more preferably 0.6% or less, and even more preferably 0.5% or less. By using the composition for forming a protective layer described later, it is possible to obtain a protective layer having high adhesiveness with the inorganic layer, high scratch resistance, and high solvent resistance as well as a low moisture content.

The film thickness of the protective layer is preferably 0.1 to 10.0 μm and more preferably 0.5 to 5.0 μm.

(Composition for Forming Protective Layer)

The protective layer can be formed by curing a composition for forming a protective layer. The composition for forming a protective layer includes a (meth)acrylate having a carbon ring and a (meth)acrylic polymer.

((Meth)acrylate Having Carbon Ring)

The carbon ring may be any of a saturated hydrocarbon ring and an unsaturated hydrocarbon ring. In addition, the carbon ring may be a monocyclic ring or may be a fused ring or a spiro ring. The number of carbon atoms included in the carbon ring is not particularly limited and is preferably 3 to 12 and more preferably 5 to 10. Specific examples of the carbon ring include a cycloalkane ring such as cyclohexane ring, a benzene ring, a naphthalene ring, a fluorene ring, an anthracene ring, or a phenanthrene ring. Among these, a benzene ring or a fluorene ring is preferable, and a fluorene ring is particularly preferable. The (meth)acrylate having a carbon ring may have only one carbon ring or may have two or more carbon rings. The two or more carbon rings may be the same as or different from each other. For example, (meth)acrylate including two or more benzene rings, (meth)acrylate including a benzene ring and a fluorene ring, and the like may be used. As a preferable example, (meth)acrylate including a biphenyl structure or a 9,9-bisphenylfluorene structure may also be used.

The (meth)acrylate having a carbon ring may have one or more (meth)acryloyl groups and preferably has two or more (meth)acryloyl groups.

Specific examples of the (meth)acrylate having a carbon ring include compounds represented by any one of Formulae (1) to (8) above, compounds described in JP2010-030290A (particularly, compounds described in paragraphs 0017 and 0018), compounds described in JP2010-030292A (particularly, compounds described in paragraphs 0013, 0019, and 0020), and compounds described in paragraphs 0014 to 0017 of JP2011-051194A.

One (meth)acrylate having a carbon ring may be used or two or more (meth)acrylates having a carbon ring may be used.

As the (meth)acrylate having a carbon ring, a (meth)acrylate having a carbon ring produced by a production method known in the related art may be used or a commercially available product may be used. Examples of the commercially available product include A-B1206PE, ABE-300, A-BPE-10, A-BPE-20, A-BPE-30, A-BPE-4, A-BPEF, and A-DCP manufactured by Shin-Nakamura Chemical Co., Ltd., EBECRYL150 and IRR 214-K manufactured by Daicel-Allnex Ltd., and LIGHT ACRYLATE DCP-A, BP-4EAL, and BP-4PA manufactured by Kyoeisha Chemical Co., Ltd.

The amount of the (meth)acrylate having a carbon ring is preferably 40% to 95% by mass, more preferably 45% to 93% by mass, even more preferably 50% to 90% by mass, and particularly preferably 55% to 85% by mass with respect to the total mass of the solid content of the composition for forming a protective layer.

((Meth)acrylic Polymer)

The (meth)acrylic polymer is a polymer of a monomer containing a derivative of (meth)acrylic acid. Examples of the derivative of (meth)acrylic acid include acrylic esters such as methyl acrylate, ethyl acrylate, and butyl acrylate, and methacrylic esters such as methyl methacrylate, ethyl methacrylate, and butyl methacrylate.

The (meth)acrylic polymer may be a homopolymer of one derivative of (meth)acrylic acid or a copolymer of two or more derivatives of (meth)acrylic acid or may be a copolymer with another monomer capable of copolymerizing with the above-described polymers. However, a copolymer of derivatives of (meth)acrylic acid is preferable.

Examples of a copolymerization component capable of copolymerizing with a derivative of (meth)acrylic acid include α,β-unsaturated acids such as acrylic acid and methacrylic acid, unsaturated acids such as unsaturated group-containing divalent carboxylic acids such as maleic acid, fumaric acid, and itaconic acid, aromatic vinyl compounds such as styrene, o-methyl styrene, m-methyl styrene, p-methyl styrene, 2,4-dimethyl styrene, p-ethyl styrene, p-tert-butyl styrene, a-methyl styrene, and α-methyl-p-methyl styrene, α,β-unsaturated nitriles such as acrylonitrile and methacrylonitrile, unsaturated carboxylic anhydrides such as a lactone ring unit, a glutaric anhydride unit, a glutarimide unit, and maleic anhydride, and maleimides such as maleimide, and N-substituted maleimide.

The weight-average molecular weight Mw of the (meth)acrylic polymer is preferably 20,000 or more and more preferably 25,000 or more from the viewpoint of mechanical strength. In addition, from the viewpoint of improving compatibility with an acrylic monomer, the weight-average molecular weight Mw of the (meth)acrylic polymer is preferably 600,000 or less and more preferably 300,000 or less.

In the present specification, the weight-average molecular weight (hereinafter, abbreviated as Mw) is a value in terms of polystyrene measured using a gel permeation chromatography (GPC). The measurement conditions given below can be used as an example of specific measurement conditions of GPC.

GPC device: HLC-8320 (manufactured by Tosoh Corporation)

Columns: TSK gel Super HZM-H, TSK gel Super HZ4000, TSK gel Super HZ2000 employed in combination (manufactured by Tosoh Corporation, 4.6 mm inner diameter (ID)×15.0 cm)

Eluent: Tetrahydrofuran (THF)

The glass transition temperature Tg of the (meth)acrylic polymer is preferably 40° C. or higher and more preferably 60° C. or higher from the viewpoint of heat resistance. From the viewpoint of adhesiveness, the glass transition temperature is preferably 110° C. or lower and more preferably 100° C. or lower.

One (meth)acrylic polymer may be used or two or more(meth)acrylic polymers may be used.

As the (meth)acrylic polymer, a (meth)acrylic polymer produced by a known method may be used or a commercially available product may be used. Examples thereof include DELPET 60N and 80N (manufactured by Asahi Kasei Chemicals Corporation) and DIANAL BR80, BR83, BR85, BR88, BR95, BR108, BR110, and BR113 (manufactured by Mitsubishi Rayon Co., Ltd.).

The amount of the (meth)acrylic polymer is preferably 5% to 40% by mass, more preferably 7% to 35% by mass, and particularly preferably 10% to 30% by mass with respect to the total mass of the solid content of the composition for forming a protective layer.

(Another Polymerizable Compound)

The composition for forming a protective layer may include another polymerizable compound other than the (meth)acrylate having a carbon ring. Examples of another polymerizable compound include polymerizable compounds described above in the composition for forming a second organic layer and the like, and a (meth)acrylate-based compound is preferable.

The amount of another polymerizable compound in the composition for forming a protective layer is preferably 0% to 10% by mass, more preferably 0% to 7% by mass, and even more preferably 0% to 5% by mass with respect to the total mass of the solid content of the composition for forming a protective layer.

(Other components and Formation of Protective Layer)

The composition for forming a protective layer may include a polymerization initiator or the like, in addition to the (meth)acrylate and (meth)acrylic polymer. For the polymerization initiator, the polymerization initiator can be used in same amount as the polymerization initiator to be added to the composition for forming a first organic layer. In addition, the composition for forming a protective layer can be formed as a composition suitable for coating or the like by using the same solvent as the solvent to be added to the composition for forming a first organic layer.

The composition for forming a protective layer may further include the same silane coupling agent as the silane coupling agent in the composition for forming a second organic layer and the like in the same amount.

The protective layer may be formed in the same manner as in the formation of the above-described first organic layer.

<Organic Electronic Device>

The gas barrier film of the embodiment of the present invention can be preferably used in an organic electronic device of which the performance is deteriorated by chemical components in air (oxygen, water, nitrogen oxides, sulfur oxides, ozone, and the like). Examples of the organic electronic device include organic electroluminescence devices, liquid crystal display devices, thin film transistors, touch panels, electronic papers, and solar cells. The gas barrier film of the embodiment of the present invention can be preferably used for a substrate for an organic electronic element for providing an organic electronic element or a sealing member for sealing an organic electronic element in an organic electronic device.

[Organic Electroluminescence Device]

The organic electroluminescence device has a portion including a substrate, an organic electroluminescent element, and the gas barrier film in this order in a thickness direction of the substrate. The “organic electroluminescence device” is sometimes referred to as “organic EL device” in the present specification. The gas barrier film is preferably used as a sealing member for sealing the substrate or the organic electroluminescent element in the organic electroluminescence device. In a case where the gas barrier film of the embodiment of the present invention is used in the organic electroluminescence device, the organic electroluminescent element may be provided on the surface opposite to the substrate side in the interface of the first organic layer.

As one sealing method for the organic electroluminescent element, a solid sealing method may be used. This method is a method in which a protective layer for an organic electroluminescent element is formed on an organic electroluminescent element on a substrate, and then an adhesive layer and a gas barrier film are laminated and cured. The protective layer of the gas barrier film of the embodiment of the present invention exhibits good adhesiveness with an adhesive layer. An adhesive for forming the adhesive layer is not particularly limited, and examples thereof include a thermosetting epoxy resin, a photocurable epoxy resin, and a photocurable acrylate resin. Among these, from the viewpoint in which water vapor transmission is not easy, a photocurable epoxy resin is preferable.

Examples of the organic EL device in which the gas barrier film is used are described in detail in JP2007-030387A. In addition, in an organic TFT device, the gas barrier film can be incorporated in the device as a gas barrier film also functioning as a λ/4 plate.

(Organic Electroluminescent Element)

The organic electroluminescent element is configured to include an electrode which becomes a cathode, an electrode which becomes an anode and further include an organic electroluminescent layer between the two electrodes.

Regarding the electrodes in the organic electroluminescence device, either of one electrode which is arranged on the substrate side and one electrode which is arranged on the sealing member side may be a reflecting electrode and the other electrode may be a transparent electrode. It is also preferable that one electrode which is arranged on the substrate side is a transparent electrode and the other electrode which is arranged on the sealing member side is a reflecting electrode.

The organic electroluminescent layer means a layer that may have at least a light emitting layer and may further have respective layers of a hole transport layer, an electron transport layer, a hole blocking layer, an electron blocking layer, a hole injection layer, an electron injection layer, and the like, as functional layers other than the light emitting layer,.

Regarding materials for preparing the organic electroluminescent layer, and each layer and each electrode in the organic electroluminescent layer, configurations, lamination order, and the configuration of the organic electroluminescence device, the description of paragraphs 0081 to 0122 of JP2012-155177A can be referred to.

In the organic electroluminescent element, the anode is preferably formed by coating. The anode also may be formed by printing. The anode can be formed by applying a conductive ink including a metal such as silver, aluminum, gold, or copper or a composition including an organic conductive polymer. Out of these, the anode is preferably formed by applying a composition including an organic conductive polymer. Examples of the organic conductive polymer include organic conductive polymers described in paragraphs 0015 to 0020 of JP2014-197500A. The anode may include polystyrene sulfonic acid, polyvinyl sulfonic acid, or the like as a dopant. As a method of forming the anode, the description regarding a method of forming a conductive film in paragraphs 0035 to 0043 of JP2014-197500A can be referred to.

In addition, a wiring in paragraph 0055 of JP2014-197500A is also preferably provided between the anode and the substrate. The wiring may be a wiring having resistance lower than that of the anode. The wiring may include a metal such as silver, aluminum, gold, or copper. The wiring can be formed by vacuum-depositing the metal and performing etching using a photolithography or a mask. In addition, wiring can also be formed by printing or applying a conductive ink including the metal.

(Substrate and Sealing Member)

The respective shapes and the sizes of the substrate and the sealing member are not particularly limited and can be appropriately selected according to the purposes. The shape may be, for example, a flat plate shape or the like. As the structure, a single layer structure may be adopted or a laminated structure may be adopted. The size can be appropriately selected according to the size of a functional laminating material or the like. For at least any one selected from the substrate and the sealing member, the gas barrier film of the embodiment of the present invention may be used. Arrangement may be performed such that the outermost surface on the organic electroluminescent element side becomes the surface opposite to the film substrate as seen from the first organic layer. That is, in a case of a configuration including a substrate for an organic electroluminescence device in which the organic electroluminescent element is provided on the surface of the gas barrier film of the embodiment of the present invention, a film substrate, a first organic layer, and an organic electroluminescent element may be provided in this order. In addition, in a case of using the gas barrier film of the embodiment of the present invention for sealing, a film substrate, a first organic layer, an organic electroluminescent element, and a substrate on which an organic electroluminescent element is provided on the surface thereof may be provided in this order.

In the organic electroluminescence device, as any one selected from the substrate and the sealing member, an inorganic material such as glass (as alkali-free glass and soda lime glass) may be used.

### EXAMPLES

The present invention is described with greater specificity below through Examples. The materials, amounts used, ratios, processing contents, processing procedures, and the like that are indicated in the Examples below can be suitably modified without departing from the spirit of the present invention. Accordingly, the scope of the present invention is not limited by the specific examples given below.

[Preparation of Gas Barrier Film]

### Example 1

As a film substrate, a PEN film having a thickness of 100 μm (Q65FA, manufactured by Teijin Dupont Film Co.) was used.

29.1 g of a compound A-1 (A-DCP, manufactured by Shin-Nakamura Chemical Co., Ltd.), 0.9 g of an ultraviolet polymerization initiator (ESACURE KT046, manufactured by Lamberti S.p.A), and 70 g of 2-butanone (manufactured by Wako Pure Chemical Industries, Ltd.) were mixed and a coating (composition for forming an undercoat organic layer) for forming an undercoat organic layer was prepared. The concentration of solid contents of the coating was 30% by mass.

The composition for forming an undercoat organic layer was applied to the surface of the prepared film substrate (PEN film) to have a film thickness of 2 μm. The composition was applied using a die coater. After the application, the undercoat organic layer was dried for 3 minutes at 80° C. in an oven.

Next, the undercoat organic layer was cured by being irradiated with ultraviolet rays from a high pressure mercury lamp (at a cumulative irradiation dose of about 600 mJ/cm²) in a chamber in which the oxygen concentration was set to 0.1% by a nitrogen substitution method.

On the undercoat organic layer after curing, a first inorganic layer formed of a silicon nitride film having a film thickness of 40 nm was formed.

The first inorganic layer was formed by using a capacitively coupled plasma (CCP)-CVD device (manufactured by Samco Inc.). As a material gas, silane gas (flow rate: 160 sccm: a standard condition at 0° C. and 1 atmospheric pressure, hereinafter the same will be applied), ammonia gas (flow rate: 370 sccm), hydrogen gas (flow rate: 590 sccm), and nitrogen gas (flow rate: 240 sccm) were used. The film forming pressure was set to 40 Pa. A power source of high frequency of 13.56 MHz frequency was used as a power source, and the plasma excitation power was set to 2.5 kW.

A first organic layer was formed on the first inorganic layer in the same manner as in the formation of the undercoat organic layer except that instead of the composition for forming an undercoat organic layer used in the formation of the undercoat organic layer, a polymerizable composition (composition for forming a first organic layer) for forming a first organic layer shown in Table 1 was used. Thus, a gas barrier film of Example 1 was obtained.

### Examples 2 to 4 and Comparative Examples 1 and 2

Gas barrier films of Examples 2 to 4 and Comparative Examples 1 and 2 were prepared in the same procedure as in Example 1 except that the composition for forming an undercoat organic layer and the composition for forming a first organic layer (components excluding the solvent) were changed as shown in Table 1.

### Example 6

A gas barrier film of Example 6 was prepared in the same procedure as in Example 1 except that the composition for forming an undercoat organic layer and the composition for forming a first organic layer (components excluding the solvent) in the preparation of the gas barrier film of Example 1 were changed to each composition shown in Table 1 (Table 2), and further, a second inorganic layer was formed. In the gas barrier film of Example 6, the second inorganic layer is provided on the surface of the first organic layer of the laminate including the undercoat organic layer, the first inorganic layer, and the first organic layer in this order on the film substrate. The second inorganic layer was provided in the same procedure as in the formation of the first inorganic layer.

### Examples 5, and 7 to 16, and Comparative Examples 3 to 6

Gas barrier films of Examples 5, and 7 to 16, and Comparative Examples 3 to 6 were prepared in the same procedure as in Example 6 except that the composition for forming an undercoat organic layer and the composition for forming a first organic layer (components excluding the solvent) in the preparation of the gas barrier film of Example 6 were changed to each composition shown in Table 1 (Table 2), and further, a second organic layer was formed. In these gas barrier films, the second organic layer or the protective layer is provided on the surface of the second inorganic layer of the laminate including the undercoat organic layer, the first inorganic layer, the first organic layer, and the second inorganic layer in this order on the film substrate. The second organic layer or the protective layer was provided in the same procedure as in the formation of the first inorganic layer using each composition shown in Table 1.

[Evaluation of Gas Barrier Film]

The following evaluations were performed on each of the obtained gas barrier films.

(Adhesiveness)

The adhesiveness between each layer was evaluated by a cross-cut peeling test according to JIS K5400.

The surface of each gas barrier film was cut with a cutter knife at an angle of 90° to the film surface at intervals of 1 mm to prepare a lattice pattern formed of 100 film pieces at intervals of 1 mm. A 2 cm-width Mylar Tape (polyester tape No. 31B, manufactured by Nitto Denko Corporation) was attached thereto and the tape was peeled off in a direction at 90° with respect to the film surface three times. The number of film pieces of the all layers that remained was counted and the adhesiveness was evaluated based on the following standard. The results are shown in Table 1.

A: The number of film pieces of the remained protective layer was 100.

B: The number of film pieces of the remained protective layer was 91 to 99.

C: The number of film pieces of the remained protective layer was 90 or less.

(Gas Barrier Properties)

The water vapor transmission rate of each gas barrier film was measured by a calcium corrosion method (a method described in JP2005-283561A), and gas barrier properties were evaluated based on the following standard. The results are shown in Table 1.

A: less than 1×10⁻⁵ [g/(m²·day)]

B: 1×10⁻⁵ [g/(m²·day)] or more and less than 5×10⁻⁵ [g/(m²·day)]

C: 5×10⁻⁵ [g/(m²·day)] or more and less than 1×10⁻⁴ [g/(m²·day)]

D: 1×10⁻⁴ [g/(m²·day)] or more

[Preparation of Organic Electroluminescent Element]

The gas barrier film of each of Examples 5 to 16 and Comparative Examples 3 to 6 cut into a size of 40 mm square was prepared as a substrate.

An Al layer having a film thickness of 200 nm was deposited on the substrate surface (the surface of the gas barrier film opposite to the film substrate) as a lead-out electrode. Poly(3,4-ethylenedioxythiophene)/polystyrene sulfonic acid (PEDOT.PSS, Orgacon 5305, manufactured by Sigma-Aldrich Co. LLC.) was applied thereto using a spin coater to have a film thickness of 100 nm. The film after application was dried in an oven at 130° C. for 30 minutes to form an anode. Sequentially, α-NPD:Bis[N-(1-naphthyl)-N-phenyl]benzidine was deposited on the surface of the formed anode to form a hole transport layer having a film thickness of 29 nm, a light emitting layer doped with 5% Ir(ppy)₃(Tris(2-phenylpyridinato)iridium) using CBP(4,4′-Bis(carbazol-9-yl)biphenyl) as a host material was formed by deposition to have a film thickness of 20 nm, BAlq(Bis-(2-methyl-8-quinolinolato)-4-(phenyl-phenolate)-aluminium(III)) was deposited to form a hole blocking layer having a film thickness of 10 nm. Then, Alq₃(Tris(8-hydroxy-quinolinato)aluminium) was deposited to form an electron transport layer having a film thickness of 20 nm. Thus, an organic electroluminescent layer was formed.

Subsequently, a LiF film having a film thickness of 0.5 nm and an Al film having a film thickness of 100 nm were deposited on the surface of the obtained organic electroluminescent layer in this order to form a cathode. Thus, an organic electroluminescent element was formed on the surface of the gas barrier film.

(Preparation of Organic EL Device)

An adhesive (XNR-5516Z, manufactured by Nagase ChemteX Corporation) was applied to cap glass for sealing with a size of 33 mm square using a dispenser. In the nitrogen atmosphere, the organic electroluminescent element was sealed with the cap glass to which the adhesive was applied. The adhesive was cured by being irradiated with ultraviolet rays from a metal halide lamp (at a cumulative irradiation dose of about 6 J/cm²) to form an organic EL device.

(Durability Evaluation)

The organic EL device was left to stand in a thermohygrostat bath at 60° C. and 90% for 500 hours.

The organic EL device after being left to stand emitted light upon application with a voltage of 7 V using a source measure unit (SMU 2400 model, manufactured by Keithley Instruments, Inc.). The light emitting surface was observed using a microscope and the total area of dark spots with respect to the area of the light emitting surface was calculated and the durability was evaluated based on the following standard. The results are shown in Table 1.

A: The total area of dark spots was less than 5%.

B: The total area of dark spots was 5% to 20%.

C: The total area of dark spots was more than 20%.

TABLE 1

| | Undercoat | First | | |
|---|---|---|---|---|
| | organic | organic | | Barrier |
| | layer | layer | Adhesiveness | properties |
| Example 1 | 1 | 3 | A | B |
| Example 2 | 2 | 4 | A | B |
| Example 3 | 4 | 4 | A | B |
| Example 4 | 2 | 5 | A | B |
| Comparative | 2 | 14 | A | C |
| Example 1 | | | | |
| Comparative | 2 | 2 | C | C |
| Example 2 | | | | |

| | | | Second | | | |
|---|---|---|---|---|---|---|
| | Undercoat | First | organic layer | | | |
| | organic | organic | or protective | | Barrier | |
| | layer | layer | layer | Adhesiveness | properties | Durability |
| Example 5 | 1 | 3 | 3 | A | A | A |
| Example 6 | 2 | 4 | — | A | A | A |
| Example 7 | 2 | 4 | 4 | A | A | A |
| Example 8 | 2 | 4 | 6 | A | A | A |
| Example 9 | 4 | 4 | 4 | A | A | A |
| Example 10 | 15 | 4 | 4 | A | A | A |
| Example 11 | 2 | 7 | 7 | A | A | A |
| Example 12 | 2 | 8 | 4 | A | A | A |
| Example 13 | 9 | 10 | 10 | A | A | A |
| Example 14 | 2 | 11 | 11 | A | A | A |
| Example 15 | 2 | 12 | 12 | A | A | A |
| Example 16 | 2 | 5 | 5 | A | B | B |
| Comparative | 14 | 14 | 14 | A | D | C |
| Example 3 | | | | | | |
| Comparative | 15 | 16 | 16 | A | B | C |
| Example 4 | | | | | | |
| Comparative | 2 | 13 | 13 | B | B | C |
| Example 5 | | | | | | |
| Comparative | 2 | 2 | 2 | C | C | C |
| Example 6 | | | | | | |

Numbers of “1” to “16” shown in the columns of “Undercoat organic layer”, “First organic layer” and “Second organic layer or protective layer” of Table 1 correspond to numbers of “Polymerizable composition 1” to “Polymerizable composition 16” in Table 2. The added amount in Table 2 is expressed by parts by mass.

TABLE 2

| | | | | | Silane coupling agent | | |
|---|---|---|---|---|---|---|---|
| | (Meth)Acrylate | | | | | | Volatilization |
| | Added | | | Tg | Added | | amount |
| | amount | Compound | CLogP | (° C.) | amount | Compound | (%) |
| Polymerizable | 100 | A-1 | 4.69 | 190 | 0 | — | — |
| composition 1 | | | | | | | |
| Polymerizable | 100 | A-2 | 8.03 | >200 | 0 | — | — |
| composition 2 | | | | | | | |
| Polymerizable | 93 | A-1 | 4.69 | 190 | 2 | X-12-1050 | 1 |
| composition 3 | | | | | | | |
| Polymerizable | 93 | A-2 | 8.03 | >200 | 2 | X-12-1050 | 1 |
| composition 4 | | | | | | | |
| Polymerizable | 93 | A-3 | 5.95 | 75 | 2 | X-12-1050 | 1 |
| composition 5 | | | | | | | |
| Polymerizable | 78 | A-2 | 8.03 | >200 | 2 | X-12-1050 | 1 |
| composition 6 | | | | | | | |
| Polymerizable | 98 | A-2 | 8.03 | >200 | 2 | X-12-1050 | 1 |
| composition 7 | | | | | | | |
| Polymerizable | 73 | A-2 | 8.03 | >200 | 2 | X-12-1050 | 1 |
| composition 8 | | | | | | | |
| Polymerizable | 100 | A-4 | 8.53 | >200 | 0 | — | — |
| composition 9 | | | | | | | |
| Polymerizable | 93 | A-4 | 8.53 | >200 | 2 | X-12-1050 | 1 |
| composition | | | | | | | |
| 10 | | | | | | | |
| Polymerizable | 93 | A-2 | 8.03 | >200 | 2 | KBM-5803 | 2 |
| composition | | | | | | | |
| 11 | | | | | | | |
| Polymerizable | 93 | A-2 | 8.03 | >200 | 2 | KR-513 | 3 |
| composition | | | | | | | |
| 12 | | | | | | | |
| Polymerizable | 93 | A-2 | 8.03 | >200 | 2 | KBM-5103 | 71 |
| composition | | | | | | | |
| 13 | | | | | | | |
| Polymerizable | 93 | A-5 | 3.81 | 120 | 2 | X-12-1050 | 1 |
| composition | | | | | | | |
| 14 | | | | | | | |
| Polymerizable | 100 | A-6 | 3.39 | >200 | 0 | — | — |
| composition | | | | | | | |
| 15 | | | | | | | |
| Polymerizable | 93 | A-6 | 3.39 | >200 | 2 | X-12-1050 | 1 |
| composition | | | | | | | |
| 16 | | | | | | | |

| | | | | | Added | |
|---|---|---|---|---|---|---|
| | | | | | amount of | |
| | Polymer | | Others | | polymerization | |
| | Added | | Added | | initiator | Moisture |
| | amount | Compound | amount | Compound | KTO46 | content % |
| Polymerizable | 0 | — | 0 | — | 3 | 0.42 |
| composition 1 | | | | | | |
| Polymerizable | 0 | — | 0 | — | 3 | 0.32 |
| composition 2 | | | | | | |
| Polymerizable | 5 | DIANAL | 0 | — | 3 | 0.47 |
| composition 3 | | BR113 | | | | |
| Polymerizable | 5 | DIANAL | 0 | — | 3 | 0.37 |
| composition 4 | | BR113 | | | | |
| Polymerizable | 5 | DIANAL | 0 | — | 3 | 0.35 |
| composition 5 | | BR113 | | | | |
| Polymerizable | 20 | DIANAL | 0 | — | 3 | 0.39 |
| composition 6 | | BR113 | | | | |
| Polymerizable | 0 | — | 0 | — | 3 | 0.37 |
| composition 7 | | | | | | |
| Polymerizable | 5 | DIANAL | 20 | A-6 | 3 | 0.60 |
| composition 8 | | BR113 | | | | |
| Polymerizable | 0 | — | 0 | — | 3 | 0.20 |
| composition 9 | | | | | | |
| Polymerizable | 5 | DIANAL | 0 | — | 3 | 0.26 |
| composition | | BR113 | | | | |
| 10 | | | | | | |
| Polymerizable | 5 | DIANAL | 0 | — | 3 | 0.37 |
| composition | | BR113 | | | | |
| 11 | | | | | | |
| Polymerizable | 5 | DIANAL | 0 | — | 3 | 0.33 |
| composition | | BR113 | | | | |
| 12 | | | | | | |
| Polymerizable | 5 | DIANAL | 0 | — | 3 | 0.37 |
| composition | | BR113 | | | | |
| 13 | | | | | | |
| Polymerizable | 5 | DIANAL | 0 | — | 3 | 1.38 |
| composition | | BR113 | | | | |
| 14 | | | | | | |
| Polymerizable | 0 | — | 0 | — | 3 | 1.47 |
| composition | | | | | | |
| 15 | | | | | | |
| Polymerizable | 5 | DIANAL | 0 | — | 3 | 1.44 |
| composition | | BR113 | | | | |
| 16 | | | | | | |

In the table, the added amount is shown by parts by mass.

The methods of measuring each physical property value in Table 2 are as follows.

The ClogP value was calculated using Chemdraw (registered trademark).

The glass transition temperature (Tg) was measured in the following procedure. each (meth)acrylate and a polymerization initiator (ESACURE KTO46, manufactured by Lamberti S.p.A) were mixed at a mass ratio of 97:3 to obtain each polymerizable composition. The obtained polymerizable composition was put into a petrie dish and cured in the same manner as in Example 1 to obtain a film piece. With respect to the obtained film piece, the glass transition temperature was measured using a DSC device. For DSC measurement conditions, the DSC measurement conditions described in the present specification were used.

The volatilization amount is a volatilization amount at 105° C. and was obtained as follows.

2.0 g of each silane coupling agent was poured into a 50 mL beaker and the volatilization amount was calculated from the mass before and after heating for 3 hours at 105° C. by the following expression.

(mass before heating−mass after heating)/(mass before heating)×100

The moisture content is a value measured as follows.

10 g of each polymerizable composition was put into a petrie dish and dried at 80° C. for 5 minutes. Then, the polymerizable composition was irradiated with ultraviolet rays from a high pressure mercury lamp (at a cumulative irradiation dose of about 600 mJ/cm²) in a chamber in which the oxygen concentration was set to 0.1% by a nitrogen substitution method to obtain a cured article. The obtained cured article was dried overnight in a vacuum oven at 0.133 Pa (1×10⁻³ torr) and 110° C. The moisture content when the cured article obtained by drying was left to stand under the environment of 25° C. and 50% RH for 3 days was measured by a Karl Fischer method and the moisture content of the organic layers formed from each polymerizable composition was calculated. The Karl Fischer method followed the description of JIS K0113.

In addition, in Table 2, the structure of each (meth)acrylate is as follows.
A-1: A-DCP, manufactured by Shin-Nakamura Chemical Co., Ltd.

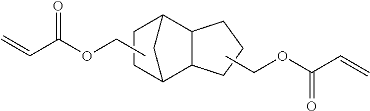

A-2: A-BPEF, manufactured by Shin-Nakamura Chemical Co., Ltd.

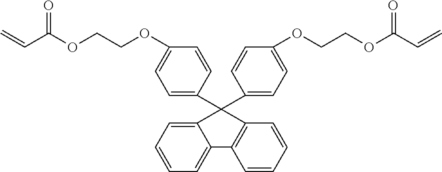 [SMILES: C=CC(=O)OCCOc1ccc(C2(c3ccc(OCCOC(=O)C=C)cc3)c3ccccc3-c3ccccc32)cc1]

A-3: ARONIX M-211B, manufactured by Toagosei Co., Ltd.

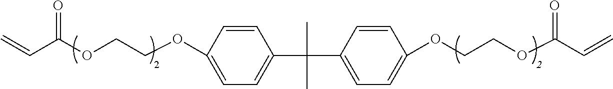

A-4: synthesized by the method described in paragraph [0036] of JP5732362B

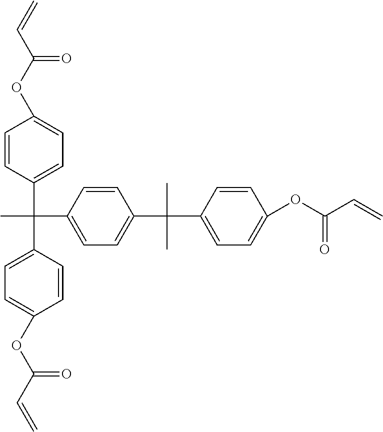 [SMILES: C=CC(=O)Oc1ccc(C(C)(C)c2ccc(C(C)(c3ccc(OC(=O)C=C)cc3)c3ccc(OC(=O)C=C)cc3)cc2)cc1]

A-5: ARONIX M-310, manufactured by Toagosei Co., Ltd.

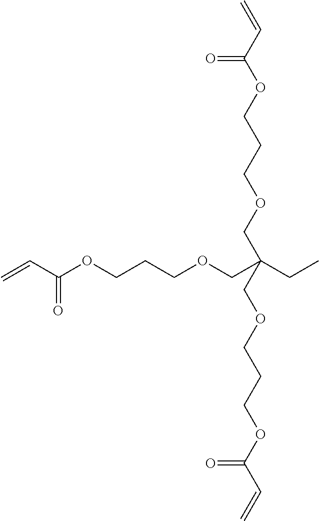 [SMILES: C=CC(=O)OCCCOCC(CC)(COCCCOC(=O)C=C)COCCCOC(=O)C=C]

A-6: ARONIX M-309, manufactured by Toagosei Co., Ltd.

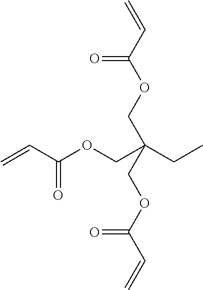 [SMILES: C=CC(=O)OCC(CC)(COC(=O)C=C)COC(=O)C=C]

All silane coupling agents of KR-513, X-12-1050, KBM5803, and KBM5103 (3-acryloxypropyltrimethoxysilane) are silane coupling agents having a(meth)acryloyl group manufactured by Shin-Etsu Chemical Co., Ltd.

DIANAL BR113 is a meth (acrylic) polymer manufactured by Mitsubishi Rayon Co., Ltd.

What is claimed is:

1. A gas barrier film comprising, in order:
a film substrate;
a first inorganic layer; and
a first organic layer,
wherein the first inorganic layer is in direct contact with the first organic layer,
the first organic layer is a layer formed by curing a composition including (meth)acrylate and a silane coupling agent,
the (meth)acrylate has a CLogP of 4.0 or more, and
the silane coupling agent has a (meth)acryloyl group and has a volatilization amount of less than 5.0% at 105° C.

2. The gas barrier film according to claim 1,
wherein a molecular weight of the silane coupling agent is 300 or more.

3. The gas barrier film according to claim 1,
wherein the silane coupling agent has four or more (meth)acryloyl groups.

4. The gas barrier film according to claim 1,
wherein the silane coupling agent includes a linear alkyl group having 6 or more carbon atoms.

5. The gas barrier film according to claim 1,
wherein the (meth)acrylate has two or more (meth)acryloyl groups.

6. The gas barrier film according to claim 1,
wherein the first organic layer has a film thickness of 0.1 to 10 μm.

7. The gas barrier film according to claim 1,
wherein the first inorganic layer is formed of silicon oxynitride or silicon nitride.

8. The gas barrier film according to claim 1, further comprising:
a second inorganic layer,
wherein the first organic layer is in direct contact with the second inorganic layer.

9. The gas barrier film according to claim 8,
wherein the second inorganic layer is formed of silicon oxynitride or silicon nitride.

10. The gas barrier film according to claim 8,
wherein a glass transition temperature of the (meth)acrylate after curing is 140° C. or higher.

11. The gas barrier film according to claim 8,
wherein a glass transition temperature of the (meth)acrylate after curing is 180° C. or higher.

12. The gas barrier film according to claim 8, further comprising:
a second organic layer,
wherein the second inorganic layer is in direct contact with the second organic layer.

13. The gas barrier film according to claim 12,
wherein the second organic layer is a layer formed by curing a composition including a (meth)acrylate having a CLogP of 4.0 or more, and a silane coupling agent having a (meth)acryloyl group and having a volatilization amount of less than 5.0% at 105° C.

14. The gas barrier film according to claim 12,
wherein the second organic layer has a film thickness of 0.1 to 10 μm.

15. The gas barrier film according to claim 1, further comprising:
an undercoat organic layer between the film substrate and the first inorganic layer.

16. An organic electronic device comprising:
the gas barrier film according to claim 1,

17. A substrate for an organic electroluminescence device, comprising:
the gas barrier film according to claim 1; and
an organic electroluminescent element,
wherein the organic electroluminescent element is provided on a surface of the gas barrier film, and
the film substrate, the first organic layer, and the organic electroluminescent element are arranged in this order.

18. The substrate for an organic electroluminescence device according to claim 17,
wherein the organic electroluminescent element includes an anode, a light emitting layer, and a cathode in this order, and
the anode is formed by coating.

19. An organic electroluminescence device comprising:
the substrate for an organic electroluminescence device according to claim 17.

20. An organic electroluminescence device comprising:
the gas barrier film according to claim 1;
an organic electroluminescent element; and
a substrate,
wherein the organic electroluminescent element is provided on a surface of the substrate, and
the film substrate, the first organic layer, the organic electroluminescent element, and the substrate are arranged in this order.
